(19) United States
(12) Patent Application Publication
(10) Pub. No.: US 2005/0012208 A1
(43) Pub. Date: Jan. 20, 2005

(54) Method of surface-mounting semiconductor chip on PCB

(75) Inventors: Se-young Jang, Suwon city (KR); Min-young Park, Seongnam city (KR); Soon-min Hong, Seoul City (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., Ltd., Suwon-Si (KR)

(21) Appl. No.: 10/822,669

(22) Filed: Apr. 13, 2004

(30) Foreign Application Priority Data
Jul. 18, 2003 (KR) 2003-49311

(51) Int. Cl. H01L 23/04

(52) U.S. Cl. 257/730

(57) ABSTRACT

A method of surface-mounting a semiconductor chip on a PCB, for mounting a flip chip type semiconductor chip on the PCB mounted with electronic components, that includes forming a solder bump on a conductive contact area of each semiconductor chip on a back of a semiconductor wafer mounted with a plurality of semiconductor chips, injecting underfill material on the area of the semiconductor wafer formed with the solder bump, partially hardening the underfill material to have cohesive properties, severing the semiconductor wafer into a plurality of individual semiconductor chips, arranging the severed semiconductor chips having the hardened underfill material on the PCB, and heating the PCB with a predetermined temperature. The present invention provides the surface-mounting method of the semiconductor chip having a simplified process by removing the need to have a package for the semiconductor chip transfer in the middle of the process, and not requiring strict tolerances for the minimum distance between the electronic components.

### CROSS-REFERENCE TO RELATED APPLICATIONS

This application claims the benefit of Korean Patent Application No. 2003-049311, filed Jul. 18, 2003, in the Korean Intellectual Property Office, the disclosure of which is incorporated herein by reference.

### BACKGROUND OF THE INVENTION

1. Field of the Invention

The present invention relates to a method of surface-mounting a semiconductor chip on a PCB (printed circuit board), more particularly, to a method of surface-mounting a semiconductor chip on a PCB having a simplified process that removes an additional underfill process and also has no need for a package used to transfer the semiconductor chip in the middle of a manufacturing process.

2. Description of the Related Art

According to recent trends of flattening and miniaturization of electronic products, a packaging technology that protects a semiconductor chip from the external environment is demanding a surface-mounting method with high speed and high density. A flip chip surface-mounting method without a lead frame was developed to meet this demand.

The flip chip surface-mounting method refers to a method of mounting the semiconductor chip on a PCB without packaging the semiconductor chip, or a method of connecting a bumper formed on the semiconductor chip with a connection pad printed on the PCB by soldering. When the semiconductor is mounted on the PCB in this method, there will be a gap between the semiconductor chip and the PCB due to the bumper formed on the semiconductor chip, which weakens supporting strength of the semiconductor chip. Accordingly, liquid resin is used as underfill material to form an underfill layer by injecting and hardening the liquid resin in the gap between the semiconductor chip and the PCB to support the semiconductor chip stably. As a result, this method provides stable connection and protection of the semiconductor chip.

FIG. 1 is a flow chart of a conventional method of surface-mounting a semiconductor chip on a PCB, and FIG. 2 is a schematic view of the surface-mounting method according to FIG. 1. As illustrated, the method of surface-mounting the semiconductor chip on the PCB comprises forming a solder bump at S10, severing a wafer at S20, loading the semiconductor chip onto a conveying means at S30, arranging the semiconductor chip at operation S40, reflowing at S50, injecting underfill material at S60, and hardening the underfill material at S70.

The solder bump forming operation at S10 refers to forming a solder bump 210 according to a pattern formed on a wafer 100 to have an electrical connection point formed on an active surface of the wafer 100. At S20, the wafer 100 formed with the solder bump 210 is severed into pieces of semiconductor chips 200 with a predetermined size. At S30, the severed semiconductor chip 200 is loaded onto the conveying means to prevent damage to the semiconductor chips. Herein, a chip tray 110 or a feeder tape 120 is used for the conveying means. Generally, the procedure described above is completed by a semiconductor chip manufacturer or a semiconductor chip packaging company, and the semiconductor chip 200 loaded in the chip tray 110 or the feeder tape 120 is transferred to a surface-mounting process of an electronic product manufacturer.

Subsequently, the semiconductor chip 200 transferred by the chip tray 110 or the feeder tape 120 is arranged on a PCB 400 at S40. Here, the PCB 400 is mounted with the semiconductor chip 200 and other electronic components 300 such as passive components or a connector. As the PCB 400 is mounted, the semiconductor chip 200 should be positioned with the distance of at least 2 mm from the surrounding electronic components 300 for injecting underfill material 220. The PCB 400 combined with the semiconductor chip 200 and the electronic components 300 goes through the reflowing at S50. During the reflowing operation, the solder bump 210 of the semiconductor chip 200 is electrically connected to a terminal of the PCB 400 for heating. At S50, the heating temperature required during the reflowing depends on the kind of material used for the solder bump 210.

Upon completing the reflowing at S50, the underfill material 220 is injected into a gap formed by the solder bump 210 between the semiconductor 200 and the PCB 400 at S60. As described above, the semiconductor chip 200 should be disposed with the minimum distance from the electronic components 300 for injecting the underfill material 220.

After hardening the injected underfill material 220 by heating the PCB 400 at a predetermined temperature at S70, the semiconductor chip 200 and the electronic components 300 have been surface mounted on the PCB 400.

However, the conventional surface-mounting method of the semiconductor chip on the PCB has disadvantages. For example, the process and equipment for the surface-mounting become complicated and the process takes a long time because the underfill material 220 is injected and hardened for the individual semiconductor chip 200 disposed on the PCB 400 after forming the connection point with reflowing. Furthermore, keeping the minimum distance between the semiconductor chip 200 and the electronic components 300 makes it difficult to have a high density mounting.

Furthermore, when using the chip tray 110 or the feeder tape 120, extra procedures are required to load the semiconductor chips 200 from the wafer 100 into a package in the middle of a manufacturing process and to dispose the semiconductor chips 200 unloaded from the chip tray 110 or the feeder tape 120 onto the PCB 400 for the surface-mounting process.

Additionally, the solder bumps 210 formed on the semiconductor chip 200 may be damaged during a transfer by the chip tray 110 or the feeder tape 120.

### SUMMARY OF THE INVENTION

Accordingly, it is an aspect of the present invention to provide a method of surface-mounting a semiconductor chip on a PCB having a simplified process that removes an additional underfill process with no need to use a package to transfer a semiconductor chip in the middle of the manufacturing process.

Additional aspects and advantages of the invention will be set forth in part in the description which follows and, in part, will be obvious from the description, or may be learned by practice of the invention.

The foregoing and/or other aspects of the present invention are achieved by providing a method of surface-mounting a semiconductor chip on a PCB, mounting a flip chip type semiconductor chip on the PCB mounted with other electronic components, that includes forming a solder bump on a conductive contact area of each semiconductor chip on the back of a semiconductor wafer mounted with a plurality of semiconductor chips, injecting underfill material on the area of the semiconductor wafer formed with the solder bump, hardening the underfill material partially to have cohesive properties, severing the semiconductor wafer into the plurality of semiconductor chips, arranging the severed semiconductor chips having the partially hardened underfill material on the PCB, and heating the PCB with a predetermined temperature.

According to an aspect of the invention, a heating temperature is above the temperature of a melting point of the solder bump.

According to an aspect of the invention, the underfill material is solidified during the heating.

### BRIEF DESCRIPTION OF THE DRAWINGS

The above and/or other aspects and advantages of the present invention will become apparent and more readily appreciated from the following description of the embodiments, taken in conjunction with the accompany drawings of which:

FIG. 1 is a flow chart illustrating a conventional method of surface-mounting a semiconductor chip on a PCB;

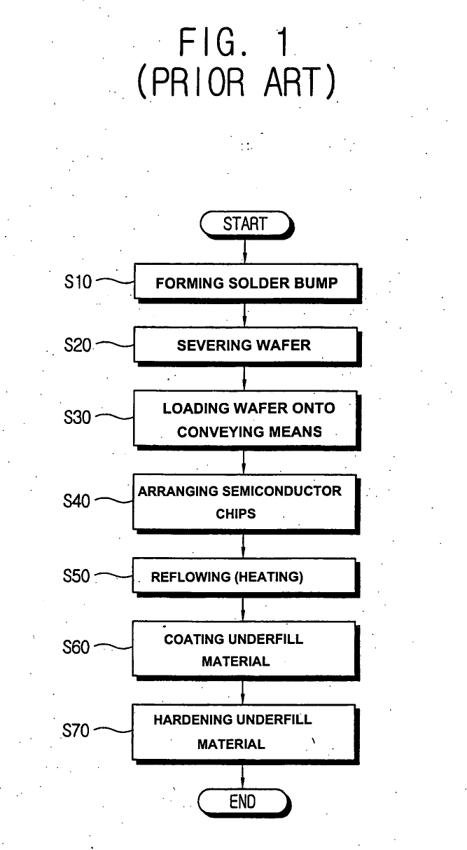

FIG. 2 is a schematic view illustrating the method of surface-mounting the semiconductor chip on the PCB in FIG. 1;

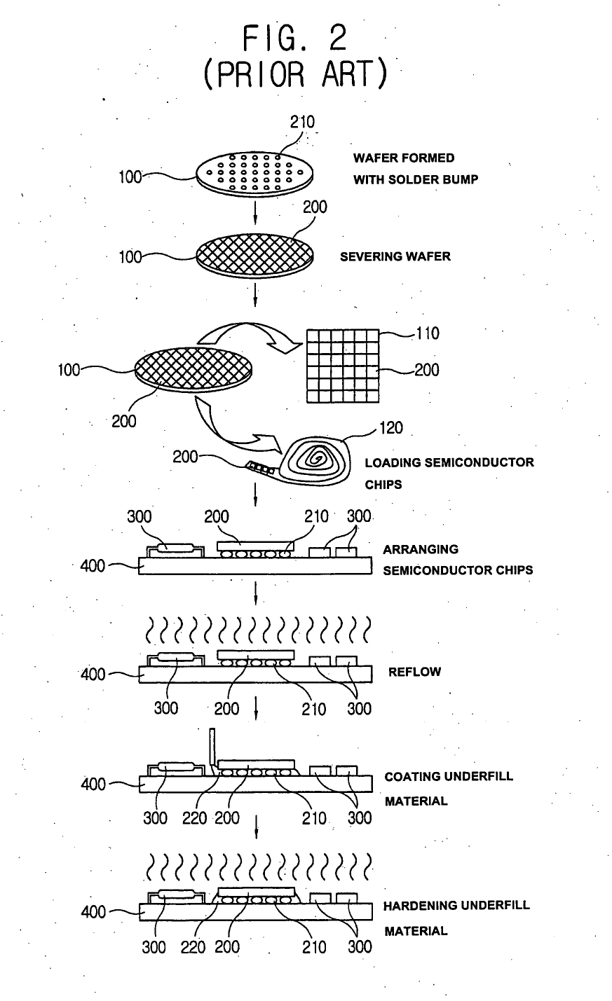

FIG. 3 is a flow chart illustrating a method of surface-mounting a semiconductor chip on a PCB according to an embodiment of the present invention;

FIG. 4 is a schematic view illustrating the method of surface-mounting the semiconductor chip on the PCB in FIG. 3.

### DETAILED DESCRIPTION OF THE EMBODIMENTS

Reference will now be made in detail to the embodiments of the present invention, examples of which are illustrated in the accompanying drawings, wherein like reference numerals refer to like elements throughout. The embodiments are described below in order to explain the present invention by referring to the figures.

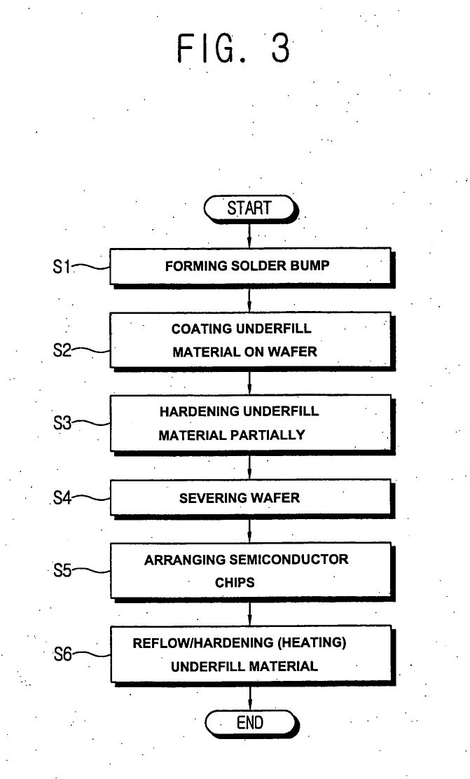

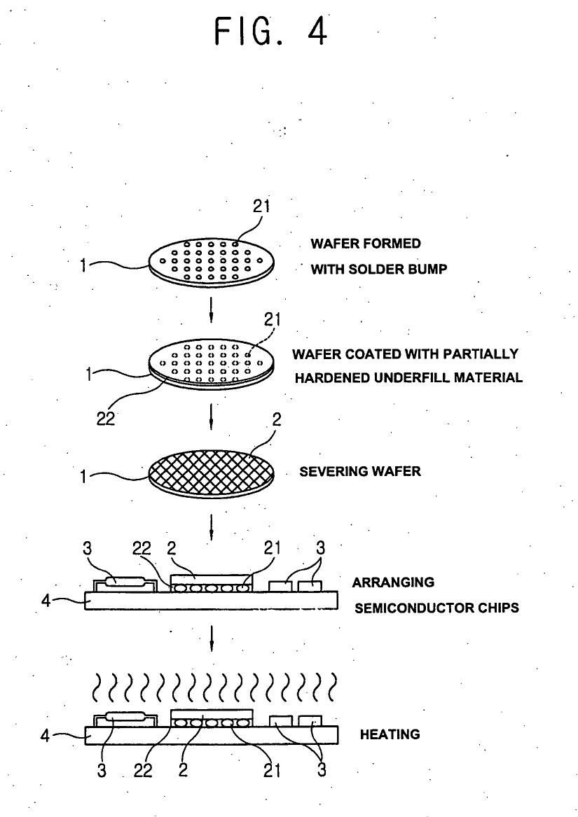

FIG. 3 is a flow chart illustrating a method of surface-mounting a semiconductor chip on a PCB according to an embodiment of the present invention, and FIG. 4 is a schematic view illustrating the method of surface-mounting the semiconductor chip on the PCB described in FIG. 3.

As illustrated, the method of surface-mounting the semiconductor chip on the PCB comprises forming solder bumps at S1, injecting underfill material at S2, partially hardening the underfill material at S3, severing a wafer at S4, disposing the semiconductor chip on the PCB at S5, and heating at S6.

At S1, the solder bumps 21 are formed on an active surface of a wafer 1 corresponding to a pattern formed on the wafer 1 to connect the semiconductor and a PCB 4 electrically. Generally, the solder bump or ball 21 is made of Sn/Pb alloy, though other alloys, including lead-free alloys, suitable for soldering may be substituted.

At S2, underfill material 22 is injected onto the wafer 1 formed with the solder bumps 21. In injecting the underfill material 22, a stencil printing method, a spin injecting method, a dipping method, or other suitable methods can be used. Although the thickness of the underfill material layer depends on the properties of the underfill material 22, the thickness of the underfill layer generally should be equal to or less than that of the solder bump 21 to enhance an electrical connection with the PCB 4. However, in alternative aspects of the present invention, the underfill layer may be greater than the solder bumps 21 in thickness because the solder bumps 21 can be electrically connected to the PCB 4 through the underfill material 22 according to a property of the underfill material 22 as the PCB 4 goes through reflowing. The underfill material 22 is typically one of various types of epoxy resins.

The underfill material 22 injected on the wafer 1 has a cohesive property after it is partially hardened at S3. At S3, the underfill material 22 injected on the wafer 1 is partially hardened by being exposed to a predetermined temperature. The underfill material 22 is partially hardened to a semisolid state because the underfill material 22 injected on the wafer in liquid state may flow down during a transfer of the wafer 1, and also because the hardened underfill material 22 has the cohesive property of binding a semiconductor chip 2 and the PCB 4. Generally, the process described above is completed by semiconductor chip manufacturers or by semiconductor chip packaging companies. Meanwhile, the wafer 1 having the partially hardened underfill material 22 is transferred to an electronic product manufacturer for a surface-mounting process.

Subsequently, the wafer 1 is severed into pieces of semiconductor chips 2 at S4. The individual semiconductor chip 2 severed out of the wafer 1 at S4 includes the solder bumps 21 and the partially hardened underfill material 22.

The severed semiconductor chip 2 is disposed on the PCB 4 mounted with electronic components 3. The semiconductor chip 2 and the electronic components 3 may be disposed on the PCB 4 at the same time, or the semiconductor chip 2 may be disposed on the PCB 4 before or after the other electronic components 3, as necessary.

At S6, the PCB 4 with the semiconductor chip 2 mounted is heated at the predetermined temperature to finish the reflowing of the solder bump 21 and the hardening of the underfill material 22 at the same time. Although the predetermined heating temperature may vary according to the properties of materials used for the underfill material 22 and the solder bump 21, generally, it should be set to a point higher than the temperature of the melting point of the solder bump 21. The solder bump 21 melts as it is heated to the predetermined temperature, and then the melted solder bump 21 chemically combines with a connection point (not shown) of the PCB 4 and forms an electrical connection. Also, the underfill material 22 hardens as the temperature increases, while the solder bump 21 is solidified and provides a stable electrical connection with the PCB 4 after the heating phase is over.

Accordingly, when the process described above is completed, the underfill material 22 is hardened to support the PCB 4 and the semiconductor 2 and to enhance the combination of the PCB 4 and the semiconductor 2 with predetermined cohesive properties.

Although the method of surface-mounting the semiconductor chip described above is related to a flip chip mounting as an example, the surface-mounting method of the semiconductor chip may also be employed in a WLCSP (wafer level chip size package) or a WLP (wafer level package) mounting. With the WLCSP or the WLP, an external package is not required because a packaging process finishes in the state of a wafer, in which semiconductor chips are arranged with the distance for surface-mounting using a thin film technology, and a solder ball is formed.

As described above, the present invention provides the method of surface-mounting the semiconductor chip having a simplified process by removing the need to have a package for the chip transfer in the middle of the process, and not requiring that the minimum distance between the electronic components be maintained as rigidly.

Although a few embodiments of the present invention have been shown and described, it will be appreciated by those skilled in the art that changes may be made in these embodiments without departing from the principles and spirit of the invention, the scope of which is defined in the appended claims and their equivalents.

1. A method of surface-mounting semiconductor chips on a PCB, including mounting a flip chip type semiconductor chip on the PCB mounted with electronic components, comprising:
forming a solder bump on a conductive contact area of each semiconductor chip on a back of a semiconductor wafer mounted with a plurality of semiconductor chips;
injecting underfill material on the area of the semiconductor wafer formed with the solder bump;
hardening the underfill material partially to have a cohesive property;
severing the semiconductor wafer into the plurality of the semiconductor chips;
arranging the severed semiconductor chips having the hardened underfill material on the PCB; and
heating the PCB at a predetermined temperature.

2. The surface-mounting method of the semiconductor chip on the PCB according to claim 1, wherein the predetermined heating temperature is above the temperature of a melting point of the solder bump.

3. The surface-mounting method of the semiconductor chip on the PCB according to claim 2, wherein the underfill material is solidified during the heating.

4. A process of preparing a wafer to be used for surface mounting a semiconductor chip on a PCB comprising:
forming a plurality of solder balls on a surface of a semiconductor wafer;
coating the surface of the semiconductor wafer formed with the solder balls with underfill material;
curing the underfill material to achieve a semisolid state.

5. The process of preparing a wafer to be used for surface mounting a semiconductor chip on a PCB as in claim 4, wherein a temperature to cure the underfill material to a semisolid state is lower than a reflow temperature of the solder balls.

6. The process of preparing a wafer to be used for surface mounting a semiconductor chip on a PCB as in claim 5, further comprising:
severing the semiconductor wafer into a plurality of semiconductor chips;
arranging the plurality of semiconductor chips on the PCB; and
raising the temperature of the PCB to a predetermined temperature.

7. The process of preparing a wafer to be used for surface mounting a semiconductor chip on a PCB as in claim 6, wherein the predetermined temperature is above the reflow temperature of the solder balls.

8. The process of preparing a wafer to be used for surface mounting a semiconductor chip on a PCB as in claim 7, wherein the underfill is cured to a solid state at the predetermined temperature.

9. The process of preparing a wafer to be used for surface mounting a semiconductor chip on a PCB as in claim 4, wherein the height of the underfill coating is approximately equal to the height of the solder balls.

10. The process of preparing a wafer to be used for surface mounting a semiconductor chip on a PCB as in claim 4, wherein the height of the underfill coating is above the height of the solder balls.

11. A process of surface mounting flip chip type semiconductor chips on a PCB comprising:
forming a plurality of solder bumps on a surface of a flip chip type semiconductor wafer;
injecting the surface of the flip chip type semiconductor wafer formed with solder bumps with underfill material to a height approximately equal to the solder bumps;
curing the underfill material to achieve a semisolid state;
severing the flip chip type semiconductor wafer into a plurality of flip chip semiconductor chips;
arranging the plurality of flip chip semiconductor chips on the PCB; and
raising the temperature of the PCB to a predetermined temperature.

12. The process as in claim 11, wherein the predetermined temperature is above a temperature that the solder bumps reflow.

13. The process as in claim 12, wherein the underfill is cured to a solid state at the predetermined temperature.

14. The process as in claim 11, further comprising operably arranging a plurality of electronic components on the PCB with at least one flip chip semiconductor chip before raising the temperature of the PCB to the predetermined temperature.
